(19) United States
(12) Patent Application Publication
(10) Pub. No.: US 2015/0102831 A1
(43) Pub. Date: Apr. 16, 2015

(54) METHOD OF INSPECTING A SEMICONDUCTOR DEVICE AND PROBING ASSEMBLY FOR USE THEREIN

(71) Applicant: SAMSUNG ELECTRONICS CO., LTD., Suwon-si (KR)

(72) Inventors: Byoung-Hun LEE, Gwangiu (KR); Yong-Hun KIM, Gwangju (KR); Young-Gon LEE, Gwangju (KR)

(73) Assignee: GWANJU INSTITUTE OF SCIENCE, Gwanju (KR)

(21) Appl. No.: 14/505,602

(22) Filed: Oct. 3, 2014

(30) Foreign Application Priority Data
Oct. 11, 2013 (KR) 10-2013-0120988

(51) Int. Cl. G01R 31/26; G01R 1/073

(52) U.S. Cl. CPC G01R 31/2607; G01R 1/073
USPC 324/754.03

(57) ABSTRACT

A probing assembly includes a TDR probe coupling a time-domain reflectometry (TDR) device with a semiconductor device including a transistor therein, the transistor having a gate electrode, a source electrode, and a drain electrode on a substrate, wherein the TDR probe includes a first probe tip connecting the gate electrode to a signal line of the TDR device, and second to fourth probe tips connecting the source electrode, the drain electrode, and a bulk region of the substrate to ground lines of the TDR device, respectively.

### CROSS-REFERENCE TO RELATED APPLICATION

Korean Patent Application No. 10-2013-0120988, filed on Oct. 11, 2013, in the Korean Intellectual Property Office, and entitled: “Method Of Inspecting A Semiconductor Device And Probing Assembly For Use Therein,” is incorporated by reference herein in its entirety.

### BACKGROUND

1. Field

Example embodiments relate to a method of inspecting a semiconductor device and a probing assembly used therein. More particularly, example embodiments relate to a method of measuring electrical characteristics of a semiconductor device based on a time-domain reflectometry (TDR) technique and the probing assembly used therein.

2. Description of the Related Art

Recently, due to potential leakage current in miniaturized semiconductor devices, in order to substitute for an existing impedance analyzer, a capacitance measurement method using a time-domain reflectometry (TDR) device has been developed. A conventional TDR capacitance voltage (C-V) measurement method may consider a leakage correction factor even if the leakage current of the semiconductor device is large, so a reliably extracted capacitance value may be required.

### SUMMARY

Example embodiments provide a probing assembly applicable to an in-line test process.

Example embodiments also provide a method of inspecting a semiconductor device using the probing assembly.

According to example embodiments, a probing assembly includes a TDR probe configured to couple a TDR device with a semiconductor device including a transistor formed therein, the transistor having a gate electrode, a source electrode and a drain electrode on a substrate. The TDR probe includes a first probe tip configured to connect the gate electrode to a signal line of the TDR device and second to fourth probe tips configured to connect the source electrode, the drain electrode and a bulk region of the substrate to ground lines of the TDR device respectively.

In example embodiments, the first probe tip may make contact with a first contact pad electrically connected to the gate electrode, and the second to fourth probe tips may make contact with second to fourth pads respectively electrically connected to the source electrode, the drain electrode and the bulk region of the substrate respectively.

In example embodiments, the first probe tip may be connected to the signal line of the TDR device, and the second to fourth probe tips may be connected to the ground lines of the TDR device respectively.

In example embodiments, the TDR device may apply a DC voltage to the semiconductor device by using the TDR probe.

In example embodiments, the TDR device may obtain a reflected waveform corresponding to the DC voltage from the semiconductor device to measure a capacitance value of the transistor.

In example embodiments, the semiconductor device may be a test structure, which is formed in a scribe lane region or a die region of a wafer.

In example embodiments, the source electrode and the drain electrode may be a source region and a drain region formed in an active region of the substrate.

According to example embodiments, in a method of inspecting the semiconductor device, a semiconductor device including a transistor having a gate electrode, a source electrode and a drain electrode on a substrate is prepared. A TDR device is coupled with the semiconductor device, wherein the gate electrode is connected to a signal line of the TDR device, and the source electrode, the drain electrode and a bulk region of the substrate are connected to ground lines of the TDR device. Electrical characteristics of the semiconductor device are measured using the TDR device.

In example embodiments, the semiconductor device may include a first contact pad electrically connected to the gate electrode, a second pad electrically connected to the source electrode, a third contact pad electrically connected to the drain electrode and a fourth contact pad electrically connected to the bulk region of the substrate respectively.

In example embodiments, coupling the TDR device with the semiconductor device may include preparing a probing assembly having a first probe tip connected to the signal line of the TDR device and second to fourth probe tips connected to the ground lines of the TDR device respectively, and contacting the first to fourth probe tips to the first to fourth contact pads respectively.

In example embodiments, measuring the electrical characteristics of the semiconductor device using the TDR device may include applying a first voltage to the semiconductor device, applying a second voltage to the semiconductor device, obtaining a first reflected waveform corresponding to the first voltage and a second reflected waveform corresponding to the second voltage from the semiconductor device and determining a capacitance value of the transistor as a function of the first and second reflected waveforms.

In example embodiments, applying the first voltage to the semiconductor device may include applying 0 volt to the gate electrode.

In example embodiments, applying the second voltage to the semiconductor device may include applying a DC voltage to the gate electrode.

In example embodiments, the method may further include measuring a current-voltage (I-V) characteristic of the transistor.

In example embodiments, the semiconductor device may be a test structure formed in a scribe lane region or a die region of a wafer.

According to example embodiments, a probing assembly including a time-domain reflectometry (TDR) device, and a TDR probe coupling the TDR device to a transistor of a semiconductor device, the transistor having a gate electrode, a source electrode, and a drain electrode on a substrate, and the TDR probe including a first probe tip connecting the gate electrode of the transistor to a signal line of the TDR device, the signal line of the TDR device being configured to transmit an electrical signal for testing the transistor, and second to fourth probe tips connecting the source electrode, the drain electrode, and a bulk region of the substrate of the transistor to respective ground lines of the TDR device.

In example embodiments, the semiconductor device may include a first contact pad electrically connected to the gate electrode, a second contact pad electrically connected to the source electrode, a third contact pad electrically connected to the drain electrode, and a fourth contact pad electrically connected to the bulk region.

In example embodiments, the first probe tip may contact the first contact pad of the semiconductor device, and the second to fourth probe tips may contact second to fourth contact pads of the semiconductor device, respectively.

In example embodiments, the TDR device may be connected to the semiconductor device without a RF-compatible test structure.

In example embodiments, the first probe tip may be directly connected to the semiconductor device.

### BRIEF DESCRIPTION OF THE DRAWINGS

Example embodiments will be more clearly understood from the following detailed description taken in conjunction with the accompanying drawings. FIGS. 1 to 6 represent non-limiting, example embodiments as described herein.

FIG. 1 illustrates a schematic diagram of a time-domain reflectometry (TDR) device to perform a semiconductor device test method in accordance with example embodiments.

FIG. 2 illustrates a view of a probing assembly connected to the TDR device in FIG. 1.

FIG. 3 illustrates a plan view of a semiconductor device test structure connected to the TDR device in FIG. 1.

FIG. 4 illustrates a cross-sectional view cut along the line II-II′ in FIG. 3.

FIG. 5 illustrates a graph of waveforms reflected from the test structure in FIG. 3.

FIG. 6 illustrates a graph of capacitances obtained from the reflected waveforms in FIG. 5.

### DETAILED DESCRIPTION

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

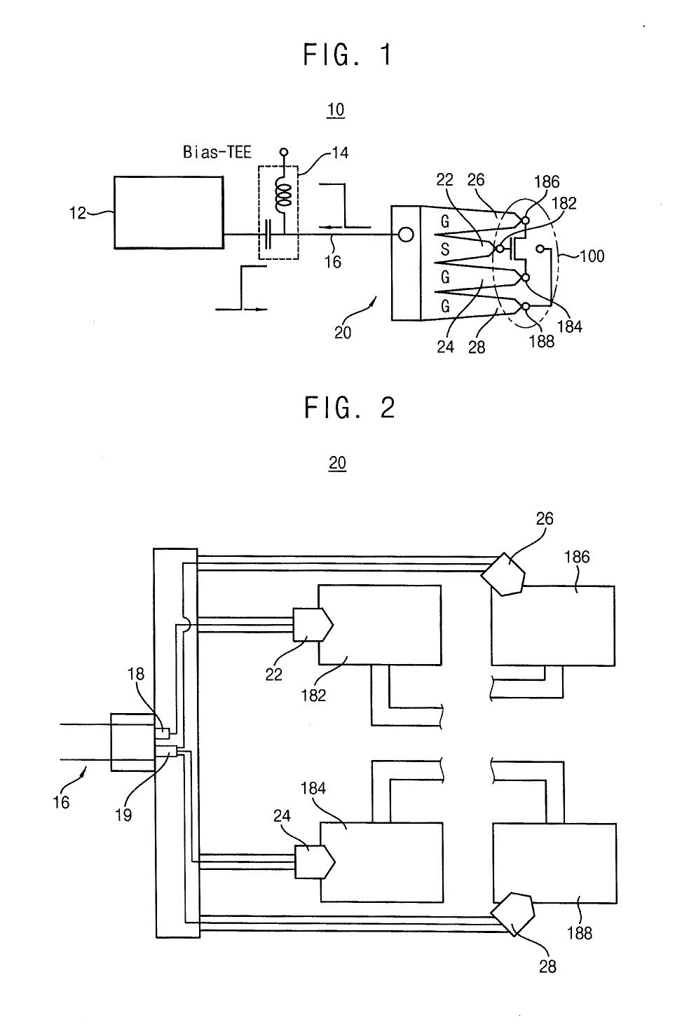

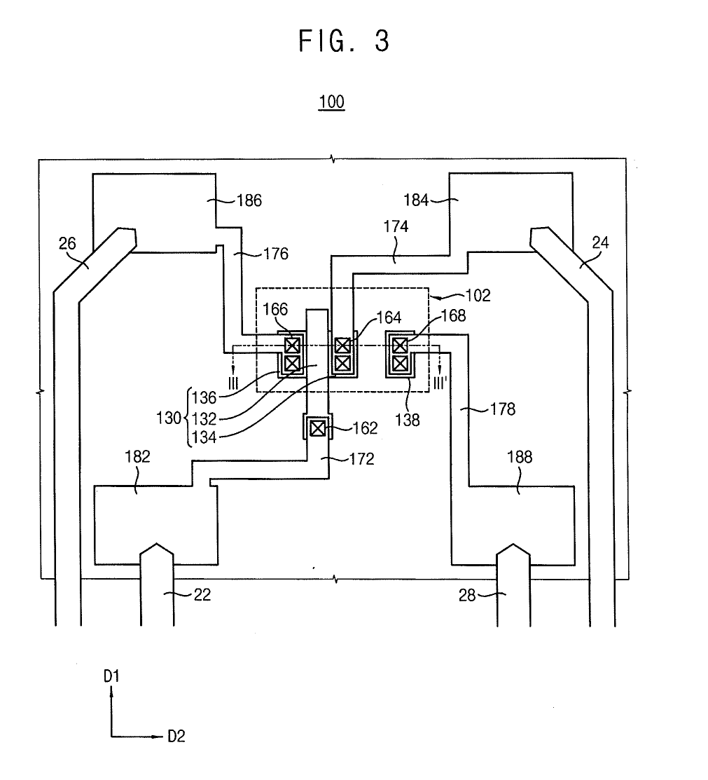

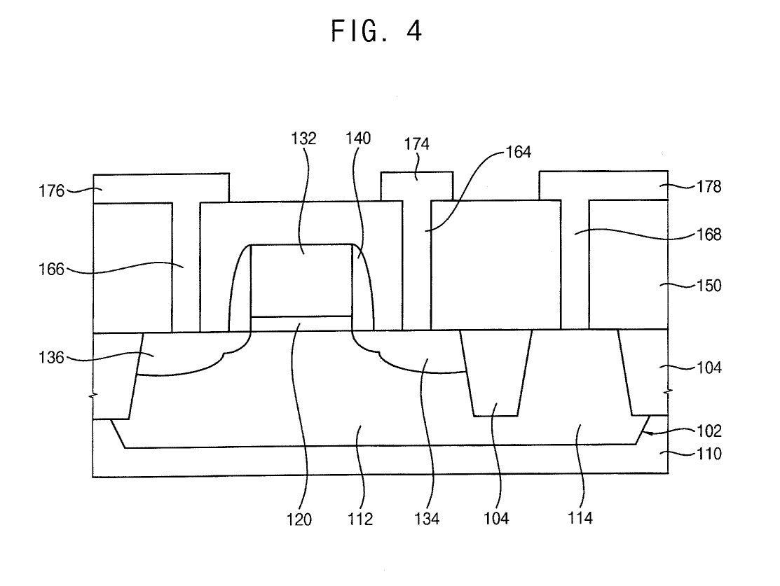

FIG. 1 illustrates a schematic view of a time-domain reflectometry (TDR) device for inspecting a semiconductor device in accordance with example embodiments. FIG. 2 illustrates an enlarged schematic view of a probing assembly connected to the TDR device in FIG. 1. FIG. 3 illustrates a view of a test structure of a semiconductor device connected to the TDR device in FIG. 1. FIG. 4 illustrates a cross-sectional view along line II-II′ in FIG. 3.

Referring to FIGS. 1 to 4, a time-domain reflectometry (TDR) device 10 may be used to measure a capacitance value of a transistor 130 in a semiconductor device 100.

First, the semiconductor device 100 including the transistor 130 to be tested is provided. In example embodiments, the semiconductor device 100 may be a test structure, which is formed in a scribe lane region or a die region of a wafer.

For example, semiconductor manufacturing processes may be performed to form the semiconductor devices 100 that include transistors and metal wires on the wafer. Then, characteristics of the semiconductor device 100 may be measured in order to evaluate the semiconductor manufacturing processes. A semiconductor device such as the test structure, i.e., the semiconductor device 100, may be referred to as a device under test (DUT). Alternatively, the transistor 130 of the semiconductor device 100 may be a cell transistor for a semiconductor chip, which is formed in the die region by sequential semiconductor manufacturing processes.

As illustrated in FIGS. 3 and 4, the semiconductor device 100 may include the transistor 130 having a gate electrode 132, a source electrode 134 and a drain electrode 136 formed on a substrate 110.

For example, the substrate 110 may include a semiconductor substrate or a glass substrate for forming integrated circuits for flat panel displays. Examples of the semiconductor substrate may be a silicon substrate, a germanium substrate, a silicon-germanium substrate, a silicon-on-insulator (SOI) substrate, a germanium-on-insulator (GOI) substrate, etc. The substrate 110 may be a semiconductor wafer including die regions having various circuit patterns formed therein, and a scribe lane region formed between the die regions. A test structure of the semiconductor device may be formed in the region of the scribe lane region or the die region.

The substrate 110 may be divided into a field region and an active region by an isolation layer 104. The isolation layer 104 may include, e.g., silicon oxide. The active region may include a first active region 112 and a second active region 114.

The transistor 130 may include the gate electrode 132 on the first active region 112, and the source region 134 and the drain region 136 at both sides of the gate electrode 132 in the first active region 112.

A gate structure may be formed on the substrate 110. The gate structure may include a gate insulation layer 120 formed on the substrate 110 and the gate electrode 132 on the gate insulation layer 120. The gate insulation layer 120 may include, e.g., silicon oxide or metal oxide. The gate electrode 132 may include, e.g., impurity-doped polysilicon, metal, metal silicide, etc. The gate structure may further include a gate spacer 140 on a sidewall of the gate electrode 132. The gate spacer 140 may include, e.g., silicon nitride or silicon oxynitride. The gate structure may have a linear shape extending in a first direction D1.

The source region 134 and the drain region 136 formed in an upper portion of the first active region 112 may serve as a source electrode and a gate electrode of the transistor. The source region 134 and the drain region 136 may include P type impurities or N type impurities. Examples of the P type impurities may be boron, gallium, indium, etc. Examples of the N type impurities may be phosphorous, arsenic, antimony, etc.

The semiconductor device 100 may further include a pad unit for transmitting an electric signal for testing the transistor 130. The pad unit may include a first contact pad 182, a second contact pad 184, a third contact pad 186, and a fourth contact pad 188. The first to fourth contact pads 182, 84, 186, and 188 may be formed on an insulation interlayer 150 covering the gate structure. The insulation interlayer 150 may include, e.g., an oxide, a nitride, or an oxynitride. The first to fourth contact pads 182, 184, 186, and 188 may include a conductive material, e.g., a metal or a metal nitride.

The first pad 182, e.g., a gate contact pad, may be electrically connected to the gate electrode 132 through a first plug 162 penetrating the insulation interlayer 150 and a gate pad connection line 172 formed on the insulation interlayer 150. The second pad 184, e.g., a source contact pad, may be electrically connected to the source region 134 through a second plug 164 penetrating the insulation interlayer 150 and a source pad connection line 174 formed on the insulation interlayer 150. The third pad 186, e.g., a drain contact pad, may be electrically connected to the drain region 136 through a third plug 166 penetrating the insulation interlayer 150 and a drain pad connection line 176 formed on the insulation interlayer 150. The fourth pad 188, e.g., a bulk contact pad, may be electrically connected to the second active region 114 through a fourth plug 168 penetrating the insulation interlayer 150 and a bulk pad connection line 178 formed on the insulation interlayer 150. The connection lines and the plugs may include a conductive material, e.g., metal or metal nitride.

The second active region 114 may be formed adjacent to the first active region 112. The second active region 114 may function as a passage through which an electrical signal is applied to a well region 102 formed in a portion of the substrate 110. That is, the electrical signal which is applied to the fourth pad 188 may be applied to the well region 102 through the bulk pad connection line 178, the fourth plug 168, and the second active region 114. The well region 102 may include P type or N type impurities.

The arrangement or locations of the first to fourth contact pads 182, 184, 186, and 188 may be changeable. In this embodiment, the semiconductor device 100 may include a transistor of a MOSFET structure. However, it is understood that the semiconductor device 100 may include various elements, e.g., FinFET, SOI FET, etc.

Referring again to FIGS. 1 to 3, the TDR device 10 may be coupled with the semiconductor device 100, and then, the TDR device 10 may be used to determine a capacitance value of the transistor 130. In example embodiments, the TDR device 10 may be coupled with the semiconductor device 100 through a probing assembly 20. Using the probing assembly 20, any one of the gate electrode 132, the source electrode 134, the drain electrode 136, and the bulk region 138 of the semiconductor device 100 may be connected to a signal line 18 of the TDR device 10, and the remaining three of them may be connected to a ground line 19 of the TDR device 10 (FIG. 2).

The probing assembly 20 may include a TDR probe having a probe tip structure of Ground-Signal-Ground-Ground (GSGG). The TDR probe may include a first probe tip 22 connected to the signal line 18 of the TDR device 10, and second to fourth probe tips 24, 26, and 28 connected to the ground line 19 of the TDR device 10. Accordingly, the signal line 18 of a transmission line 16 of the TDR device 10 may be electrically connected to the first probe tip 22, and the ground line 19 of the TDR device 10 may be electrically connected to the second to fourth probe tips 24, 26, and 28.

The first to fourth probe tips 22, 24, 26, and 28 of the probing assembly 20 may make contact with the first to fourth contact pads 182, 184, 186, and 188, respectively. The first probe tip 22 of the probing assembly 20 may make contact with the first contact pad 182, the second probe tip 24 may make contact with the second contact pad 184, the third probe tip 26 may make contact with the third contact pad 186, and the fourth probe tip 28 may make contact with the fourth contact pad 188.

Thus, the gate electrode 132 of the semiconductor device 100, i.e., which is connected to the first pad 182, may be connected to the signal line 18 of the TDR device 10 through the first probe tip 22. The source electrode 134, the drain electrode 136, and the bulk region 138 of the semiconductor device 100 may be connected to the ground line 19 through second through fourth probe tips 24 through 28, respectively. That is, through the probing assembly 20, the TDR device 10 may be, e.g., directly, connected to a gate, a source, a drain, and a substrate of the semiconductor device 100 having a general MOSFET structure, rather than to a conventional RF-compatible test structure including a source, a drain, and a substrate connected to each other.

As illustrated in FIG. 1, a TDR scope 12 may be connected to the semiconductor device 100 through a Bias-TEE 14, the transmission line 16, and the probing assembly 20. The TDR scope 12 may generate and output a step function with a relatively fast rise time to the semiconductor device 100.

Due to impedance mismatch between the transmission line 16 and the semiconductor device 100, the step function may be reflected back toward the TDR scope 12 which may monitor an input waveform and a reflected waveform as a function of time. The waveform of the reflected signal may be determined by electrical characteristics of load impedance. Accordingly, by measuring the reflected signal, the electrical characteristics of the load impedance may be accurately analyzed.

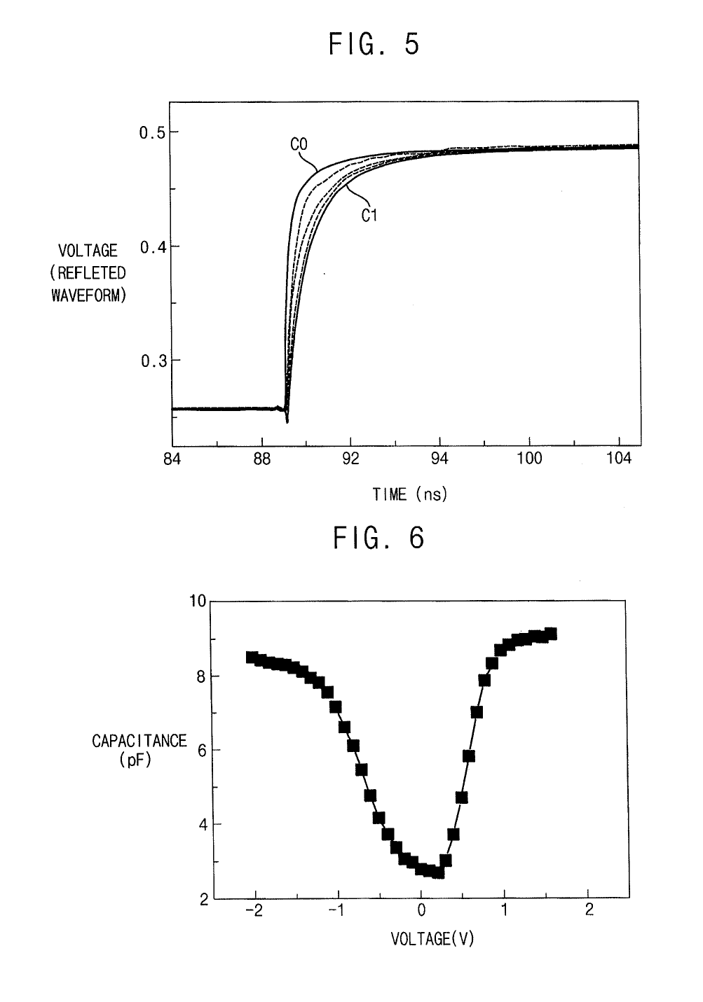

FIG. 5 illustrates a graph of a reflected waveform from the test structure of FIG. 3. FIG. 6 illustrates a graph of a capacitance of the semiconductor device acquired from the reflected waveform of FIG. 5.

As illustrated in FIG. 5, a first reflected waveform C0 from the semiconductor device 100 may be obtained, when the probing assembly 20 does not make contact with the semiconductor device 100 (open circuit). A second waveform C1 may be obtained, when a second voltage, e.g., (−2) volts, is applied to the semiconductor device 100. By applying a particular DC bias between about (−2) V and about 1.5V to the semiconductor device 100, reflected waveforms (illustrated with broken lines) between the first waveform C0 and the second waveform C1 may be obtained.

If the semiconductor device 100 is connected to the TDR device 10, an amount of electric charge for charging the transistor 130 may be proportional to the area between the first reflected waveform C0 and the second reflected waveform C1. In here, the capacitance C may be determined using the following Equation 1.

$$C = \frac{1}{2 {Z}_{0} {V}_{step}} {\int }_{0}^{∞} \vert {V}_{open} ( t ) - {V}_{TDR} ( t ) \vert d t \qquad [ Equation 1 ]$$

Wherein Vₒₚₑₙ(t) is the first reflected waveform, V_{TDR}(t) is the second reflected waveform, Vₛₜₑₚ is the height of the step function and Z₀ is the impedance of the transmission line, e.g., 50 Ohm.

As illustrated in FIG. 6, capacitance-voltage (C-V) measurements of the transistor 130 may be obtained as a function of an open circuit waveform, i.e., the first reflected waveform C0, and the reflected waveform from the semiconductor device 100 corresponding to a particular DC bias. In this embodiment, the gate insulation layer 120 of the transistor 130 may have an equivalent oxide thickness (EOT) of about 4 nm.

In example embodiments, before or after measuring the capacitance of the semiconductor device 100 using the TDR device 10, voltage-current (I-V) characteristics of the transistor 130 of the semiconductor device 100 formed on the wafer may be measured.

After predetermined manufacturing processes may be performed to form the semiconductor device 100, the capacitance of the semiconductor device 100 may be measured using the TDR device 10 as an in-line test process. Accordingly, besides the capacitance-voltage (C-V) measurements, a basic current-voltage (I-V) of the transistor 130 of the semiconductor device 100 may be measured as an in-line test process. Therefore, it is possible to measure not only the capacitance of the transistor 130 but also the basic current-voltage (I-V) and compare and analyze them.

As discussed above, the probing assembly 20 having the probe tip structure of GSGG may be used to connect the gate electrode 132 of the transistor 130 to the signal line 16, and to connect the source electrode 134, the drain electrode 136, and the bulk substrate 138 to three ground lines respectively, i.e., to ground line 19, to thereby extract the capacitance value of the transistor. Accordingly, the TDR C-V measurement method using the GSGG probe tip may be applied to a semiconductor device having a general structure, e.g., a MOSFET structure, to accurately extract the capacitance of the semiconductor device, rather than to a conventional RF-compatible test structure.

Additionally, the TDR C-V measurement method by using the GSGG probe tip may be applied to measure gate-to-channel capacitance (Cgc) and gate-to-bulk capacitance (Cgb), as well as the whole capacitance of MOSFET in a semiconductor device manufacturing line. Therefore, it is very useful to evaluating the performance of the semiconductor device by extracting the capacitance and parameters, e.g., an effective mobility or an effective length, by applying directly to an in-line testing process of a semiconductor device. Further, because the possibility of direct application to the in-line test, costs for test facilities may be reduced compared to the existing network analyzer.

By way of summary and review, a conventional TDR C-V measurement method includes a Ground-Signal-Ground (GSG) type probe tip used in a high frequency domain. However, since the conventional GSG probe tip has a limited structure that is applied to a restricted element, e.g., the conventional GSG probe may be applied to a RF element for high frequency, an additional RF-compatible element may be required for properly measuring the capacitance value.

In contrast, according to example embodiments, a probing assembly includes a Ground-Signal-Ground-Ground (GSGG) type probe tip that connects a gate electrode of a transistor, e.g., a test structure, to the signal line, and connects the remaining source electrode, drain electrode, and bulk substrate to three ground lines respectively, to thereby extract a capacitance value of the transistor. Accordingly, a TDR C-V measurement method using the GSGG probe tip may be applied to a semiconductor device having a general structure, e.g., a MOSFET, rather than an extra RF-compatible test structure, to extract an accurate capacitance value of the semiconductor device.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A probing assembly, comprising:
a TDR probe coupling a time-domain reflectometry (TDR) device with a semiconductor device including a transistor, the transistor having a gate electrode, a source electrode, and a drain electrode on a substrate,
wherein the TDR probe includes:
a first probe tip connecting the gate electrode to a signal line of the TDR device, and
second to fourth probe tips connecting the source electrode, the drain electrode, and a bulk region of the substrate to ground lines of the TDR device, respectively.

2. The probing assembly as claimed in claim 1, wherein the first probe tip contacts a first contact pad electrically connected to the gate electrode, and the second to fourth probe tips contact second to fourth contact pads electrically connected to the source electrode, the drain electrode, and the bulk region, respectively.

3. The probing assembly as claimed in claim 1, wherein the first probe tip is connected to the signal line of the TDR device, and the second to fourth probe tips are connected to the ground lines of the TDR device respectively.

4. The probing assembly as claimed in claim 1, wherein the TDR device applies DC voltage to the semiconductor device via the TDR probe.

5. The probing assembly as claimed in claim 4, wherein the TDR device obtains a reflected waveform corresponding to the DC voltage from the semiconductor device, the reflected waveform corresponding to measurement of a capacitance value of the transistor.

6. The probing assembly as claimed in claim 1, wherein the semiconductor device is a test structure in a scribe lane region or a die region of a wafer.

7. The probing assembly as claimed in claim 1, wherein the source electrode and the drain electrode are a source region and a drain region in an active region of the substrate.

8. A method of inspecting a semiconductor device, the method comprising:
preparing a semiconductor device including a transistor, the transistor having a gate electrode, a source electrode, and a drain electrode on a substrate;
coupling a time-domain reflectometry (TDR) device to the semiconductor device via a TDR probe, such that the gate electrode of the transistor is connected to a signal line of the TDR device, and the source electrode, the drain electrode, and a bulk region of the substrate are connected to respective ground lines of the TDR device; and
measuring electrical characteristics of the semiconductor device by using the TDR device.

9. The method as claimed in claim 8, wherein the semiconductor device includes:
a first contact pad electrically connected to the gate electrode;
a second contact pad electrically connected to the source electrode;
a third contact pad electrically connected to the drain electrode; and
a fourth contact pad electrically connected to the bulk region.

10. The method as claimed in claim 9, wherein coupling the TDR device with the semiconductor device includes:
preparing a probing assembly having a first probe tip connected to the signal line of the TDR device and second to fourth probe tips connected to the ground lines of the TDR device respectively; and
contacting the first to fourth probe tips to the first to fourth contact pads, respectively.

11. The method as claimed in claim 8, wherein measuring the electrical characteristics of the semiconductor device by using the TDR device includes:
applying a first voltage to the semiconductor device;
applying a second voltage to the semiconductor device;
obtaining a first reflected waveform corresponding to the first voltage and a second reflected waveform corresponding to the second voltage from the semiconductor device; and
determining a capacitance value of the transistor as a function of the first and second reflected waveforms.

12. The method as claimed in claim 11, wherein applying the first voltage to the semiconductor device includes applying zero volts to the gate electrode.

13. The method as claimed in claim 11, wherein applying the second voltage to the semiconductor device includes applying a DC voltage other than zero to the gate electrode.

14. The method as claimed in claim 11, further comprising measuring a current-voltage (I-V) characteristic of the transistor.

15. The method as claimed in claim 11, wherein preparing the semiconductor device includes forming a semiconductor test structure in a scribe lane region or a die region of a wafer.

16. A probing assembly, comprising:
a time-domain reflectometry (TDR) device; and
a TDR probe coupling the TDR device to a transistor of a semiconductor device, the transistor having a gate electrode, a source electrode, and a drain electrode on a substrate, and the TDR probe including:
a first probe tip connecting the gate electrode of the transistor to a signal line of the TDR device, the signal line of the TDR device being configured to transmit an electrical signal for testing the transistor, and
second to fourth probe tips connecting the source electrode, the drain electrode, and a bulk region of the substrate of the transistor to respective ground lines of the TDR device.

17. The probing assembly as claimed in claim 16, wherein the semiconductor device includes:
a first contact pad electrically connected to the gate electrode;
a second contact pad electrically connected to the source electrode;
a third contact pad electrically connected to the drain electrode; and
a fourth contact pad electrically connected to the bulk region.

18. The probing assembly as claimed in claim 17, wherein the first probe tip contacts the first contact pad of the semiconductor device, and the second to fourth probe tips contact second to fourth contact pads of the semiconductor device, respectively.

19. The probing assembly as claimed in claim 16, wherein the TDR device is connected to the semiconductor device without a RF-compatible test structure.

20. The probing assembly as claimed in claim 16, wherein the first probe tip is directly connected to the semiconductor device.
